(19) United States
(12) Patent Application Publication
(10) Pub. No.: US 2009/0080233 A1
(43) Pub. Date: Mar. 26, 2009

(54) METHOD AND APPARATUS FOR PRINTED RESISTIVE READ ONLY MEMORY

(75) Inventors: Kin P. TSUI, Morton Grove, IL (US); Daniel R. GAMOTA, Palatine, IL (US); Kristina KALYANASUNDARAM, Elmhurst, IL (US); John B. SZCZECH, Schaumburg, IL (US); Xiangcheng TANG, Northbrook, IL (US); Jerzy WIELGUS, Mount Prospect, IL (US); Jie ZHANG, Buffalo Grove, IL (US)

Correspondence Address: PRASS LLP, 2661 Riva Road, Bldg. 1000, Suite 1044, ANNAPOLIS, MD, 21401, US

(73) Assignee: Motorola, Inc., Schaumburg, IL (US)

(21) Appl. No.: 11/859,283

(22) Filed: Sep. 21, 2007

(51) Int. Cl. G11C 17/00

(52) U.S. Cl. 365/100

(57) ABSTRACT

A printed read only memory (ROM) device that consists of an array of memory resistors, a reference resistor, and analog-to-digital circuit is disclosed. Resistance values are dependent on the data to be stored in the read only memory. During read operation, a resistor in the array is powered, activating a voltage divider between the powered resistor and the reference resistor. The analog-to-digital circuit will read the divided voltage level between the two resistors, compare the voltage supply level and interpret it into bits of memory data. During the manufacturing of the ROM circuit, an array of memory resistors is printed as the means for storage of the data. Resistive inks of specific resistance values are selected and printed in a preferred layout that includes a reference resistor coupled to the determined array of memory resistors and an analog to digital converter so as to form a read only memory with the received data.

### BACKGROUND OF THE INVENTION

1. Field of the Invention

This invention relates, in general, to Read Only Memories (ROMs) and, more particularly, to ROMs and a method for manufacturing the printed ROMs, wherein the ROMs is programmed during the printing process.

2. Introduction

Printed electronics is a revolutionary technology that changes the way of manufacturing electronic integrated circuits (ICs). In the manufacturing process, instead of assembling individual ICs to a circuit board, entire circuitry is printed with electrically functional inks (dielectric, resistive, conductive, and semiconductive). In many applications, it is required that read-only memory is implemented for the circuit to perform defined functions. For example, in a printed point-of-sale advertising application, defined lighting sequences, timing, music information etc. should be stored with the printed signage so that the driver unit can drive the different signage designs to provide the consumer with the appropriate predetermined message.

Existing read-only silicon memory ICs provide a method of burning a large amount of data into the IC after it is sold to designers/product manufacturers as a component. Such circuitry consists of voltage breakable diodes, which can be disconnected by programmers. The circuit board assemblers would program this memory component before assembling it to a circuit board.

However, in most printed electronics based products, it is desired that memory circuitry is printed during the printing of the other functional circuits on a substrate. It is not common to find component manufacturers who pre-build thousands of blank memory components. In addition, the optimal circuit requires diodes/transistors that are printed using multiple layers of gates, dielectric, source/drain electrodes, etc. Printing circuitry requires greater control for registration between layers and chemical compatibility of material systems. Therefore, it is not a robust method for many applications such as memory-embedded printed point-of-sale advertising signage.

Accordingly, it is highly desirable to provide methods and structures which overcome these problems, which are inexpensive and easy to perform, install and use. There is also a need for memory data that can be printed on-the-fly without the additional step of later burning or programming.

### SUMMARY OF THE INVENTION

A read only memory (ROM) device that consists of an array of printed memory resistors, a reference resistor, and an analog-to-digital circuit is disclosed. Resistance values are dependent on the data to be stored in the read only memory. During read operation, a resistor in the array is powered, activating a voltage divider between the powered resistor and the reference resistor. The analog-to-digital circuit will read the divided voltage level between the two resistors, compare the voltage supply level and interpret it into bits of memory data. During the manufacturing of the ROM circuit, the data to be stored in the ROM circuit is fabricated by printing a predetermined array of memory resistors of specific resistance values. Resistive inks are deposited in a preferred print layout that includes a reference resistor coupled to the array of memory resistors and an analog to digital converter so as to form a read only memory with the received data.

### BRIEF DESCRIPTION OF THE DRAWINGS

In order to describe the manner in which the above-recited and other advantages and features of the invention can be obtained, a more particular description of the invention briefly described above will be rendered by reference to specific embodiments thereof which are illustrated in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 illustrates an exemplary diagram of a hardware and operating environment for a signage system in accordance with a possible embodiment of the invention;

FIG. 2 illustrates a block diagram of an exemplary printed resistive read-only-memory in accordance with a possible embodiment of the invention;

FIG. 3 illustrates a data table showing memory values as a function of resistor value in accordance with a possible embodiment of the invention;

FIG. 4 illustrates a block diagram of printed resistive read-only-memory in accordance with a possible embodiment of the invention;

FIG. 5 is an exemplary flowchart illustrating one possible printed resistive read-only-memory manufacturing process in accordance with one possible embodiment of the invention; and

FIG. 6 illustrates a block diagram of a signage employing a printed resistive read-only memory in accordance with a possible embodiment of the invention.

### DETAILED DESCRIPTION OF THE INVENTION

Additional features and advantages of the invention will be set forth in the description which follows, and in part will be obvious from the description, or may be learned by practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth herein.

Various embodiments of the invention are discussed in detail below. While specific implementations are discussed, it should be understood that this is done for illustration purposes only. A person skilled in the relevant art will recognize that other components and configurations may be used without parting from the spirit and scope of the invention.

The invention comprises a variety of embodiments, such as a method and apparatus and other embodiments that relate to the basic concepts of the invention.

This invention concerns a fully or hybrid printed electronic circuits that contain memory for design setting, instruction fetching, and device identification (ID) number, printed and flexible signage and displays.

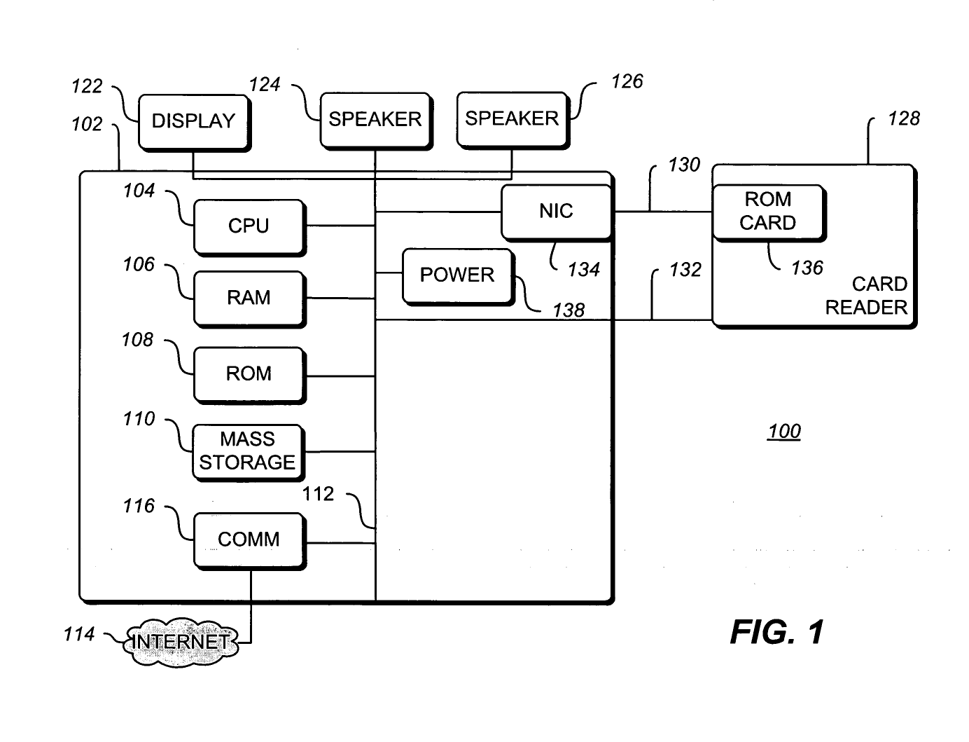

FIG. 1 illustrates in perspective view a signage device 100 according to the present invention used in a visual display at a commercial establishment. In particular, FIG. 1 illustrates the use of a printed electronic circuit for causing a computer or controller in the signage device 100 to activate a presentation in accordance with a possible embodiment of the invention. In particular, the data stored in printed resistive read-only-memory 136 is inserted into an aptly programmed card reader 128 for processing by a computer/controller 102 so as to display a message 122 or to initiate an audio presentation 124.

The signage device 100 includes a card reader 128, controller 102, a symbol-forming element such as display 122 for communicating letter or graphic designs, and audio visual devices (122,124,126) for communicating a message.

Computer/controller 102 includes a processor unit 104. Computer/controller 102 also includes random-access memory (RAM) 106, read-only memory (ROM) 108, and optional mass storage devices 110, and a system bus 112, that operatively couples various system components to the processing unit 104. The memory 106, 108, and mass storage devices, 110, are types of computer-accessible media. The processor 104 executes computer programs stored on the computer-accessible media.

Computer/controller 102 can be communicatively connected to the Internet 114 via a communication device 116. Internet 114 connectivity is well known within the art. In one embodiment, a communication device 116 is a modem that responds to communication drivers to connect to the Internet via what is known in the art as a “dial-up connection.” In another embodiment, a communication device 116 is an Ethernet® or similar hardware network card connected to a local-area network (LAN) that itself is connected to the Internet via what is known in the art as a “direct connection” (e.g., T1 line, WIFI, near field communication, Bluetooth, etc.).

A user enters commands and information into the computer 102 through an input devices such as a keyboard or a pointing device (not shown) such as mice, touch pads, trackballs, remote controls and point sticks, microphone, joystick, game pad, satellite dish, scanner, or the like. User-defined code sequences can also be programmed into the computer/controller 102 with programmer devices.

The computer/controller 102 is operatively coupled to a display device 122. Display device 122 is connected to the system bus 112. Display device 122 permits the display of information, including computer, video and other information, for viewing by a user of the computer. Embodiments are not limited to any particular display device 122. Such display devices include cathode ray tube (CRT displays (monitors), as well as flat panel displays such as liquid crystal displays LCD's), electroluminescent (EL), Organic Light Emitting Diode (OLED's), Polymer Light Emitting Diode PLED's), and reflective displays including but not limited to electrophoretic, electrowetting, and micro electro mechanical system (MEMS) based technologies. In addition to a monitor, computers typically include other peripheral input/output devices such as printers (not shown). Speakers 124 and 126 provide audio output of signals. Speakers 124 and 126 are also connected to the system bus 112.

Computer 102 also includes an operating system (not shown) that is stored on the computer-accessible media RAM 106, ROM 108, and mass storage device 110, and is executed by the processor 104. Examples of operating systems include Microsoft Windows®, Apple MacOS®, Linux®, UNIX®. Examples are not limited to any particular operating system, however, and the construction and use of such operating systems are well known within the art.

Embodiments of computer 102 are not limited to any type of computer 102. In varying embodiments, computer 102 comprises a PC-compatible computer, a MacOS®-compatible computer, a Linux®-compatible computer, or a UNIX®-compatible computer. The construction and operation of such computers are well known within the art.

Computer 102 can be operated using at least one operating system to provide a graphical user interface (GUI) including a user-controllable pointer. Computer 102 can have at least one web browser application program executing within at least one operating system, to permit users of computer 102 to access an intranet, extranet or Internet world-wide-web pages as addressed by Universal Resource Locator (URL) addresses. Examples of browser application programs include Netscape Navigator® and Microsoft Internet Explorer®.

The computer 102 can operate in a networked environment using logical connections to one or more remote card reader, such as card reader 128. These logical connections are achieved by a communication device coupled to, or a part of, the computer 102. Embodiments are not limited to a particular type of communications device. The card reader 128 can be another computer, a server, a router, a network PC, a client, a peer device or other common network node. The logical connections depicted in FIG. 1 include a local-area network (LAN) 130 and a wide-area network WAN) 132. Such networking environments are commonplace in offices, enterprise-wide computer networks, intranets, extranets and the Internet.

In the preferred environment, the card reader 128 is directly connected to computer 102. The card reader 128 could be remote from computer 102, when used in a LAN-networking environment, the computer 102 and card reader 128 are connected to the local network 130 through network interfaces or adapters 134, which is one type of communications device 116. Card reader 128 reads information or data in read-only-memory card (ROM) card 136. When used in a conventional WAN-networking environment, the computer 102 and card reader 128 communicate with a WAN 132 through modems (not shown). The modem, which can be internal or external, is connected to the system bus 112. In a networked environment, program modules depicted relative to the computer 102, or portions thereof, can be stored in card reader 128. Computer 102 also includes power supply 138. Each power supply can be a battery.

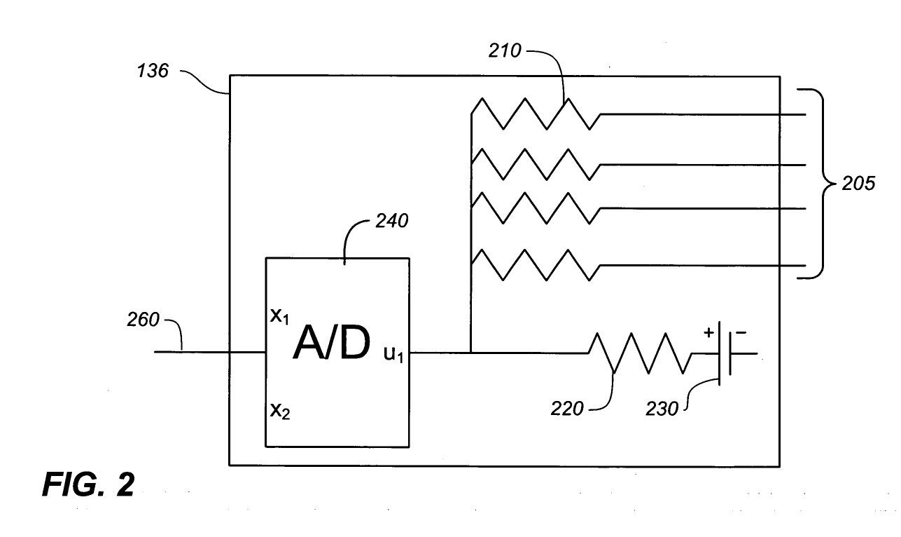

FIG. 2 illustrates an exemplary diagram of a printed electronic circuit for causing a controller to activate a signage or advertisement presentation in accordance with a possible embodiment of the invention.

In particular, the data stored in an ink printed resistive read-only-memory (ROM) 136 that has an array of memory resistors 210 that correspond to the data being stored, an ink printed reference resistor 220, a voltage source (Vdd) 230, and analog-to-digital converter 240, address lines 205, and bit value line 260 that would correspond to a 4bits system. The array of memory resistors 210 are formed from resistive inks that correspond to a desired resistor value. The analog to digital converter 240 may be an ink printed active device.

During read operation, a resistor in the array 210 is powered at a certain voltage or by grounding the resistor using one of the address lines 205 with a ground voltage (Vg=0), activating a voltage divider between the powered resistor 210 and the reference resistor 220. The analog-to-digital circuit 240 will read the divided voltage level between the two resistors, compare to voltage supply level 230, and interpret it into bits of a memory datum 260. These data are then used to define needed functions by other parts of the circuit such as computer/controller 102 in FIG. 1. The definition of the resistance follows voltage divide rule of Vo=R1/(R1+R2)*V. Either resistor 210 or resistor 220 can be the reference resistor and the other would be each resistor in the array. V is the voltage supply level 230 and Vo is the voltage between the memory resistor 210 and the reference resistor. Analog-to-digital circuit 240 divides ground voltage (Vg) and supply voltage (Vdd) into number of bits stored in each resistor power of two(2^{N}). The voltage divider output V₀ is then converted to corresponding bit value. Example, in a 4 bits system with a 5 volt supply the bits are divided into 0.3125 volts. So if a resistor is to hold four bits of data representing (0011) its resistance should be 2300Ω (Ohms) to correspond to a Vo of 0.9375 volts. The accuracy of the output level is proportional to the accuracy of the resistance of resistor 210 and reference resistor 220. In addition, the number of bits that a resistor stored is proportional to the accuracy of the output level. Rounding method should be used when selecting the most significant bits as output data. The least significant bits should be discarded.

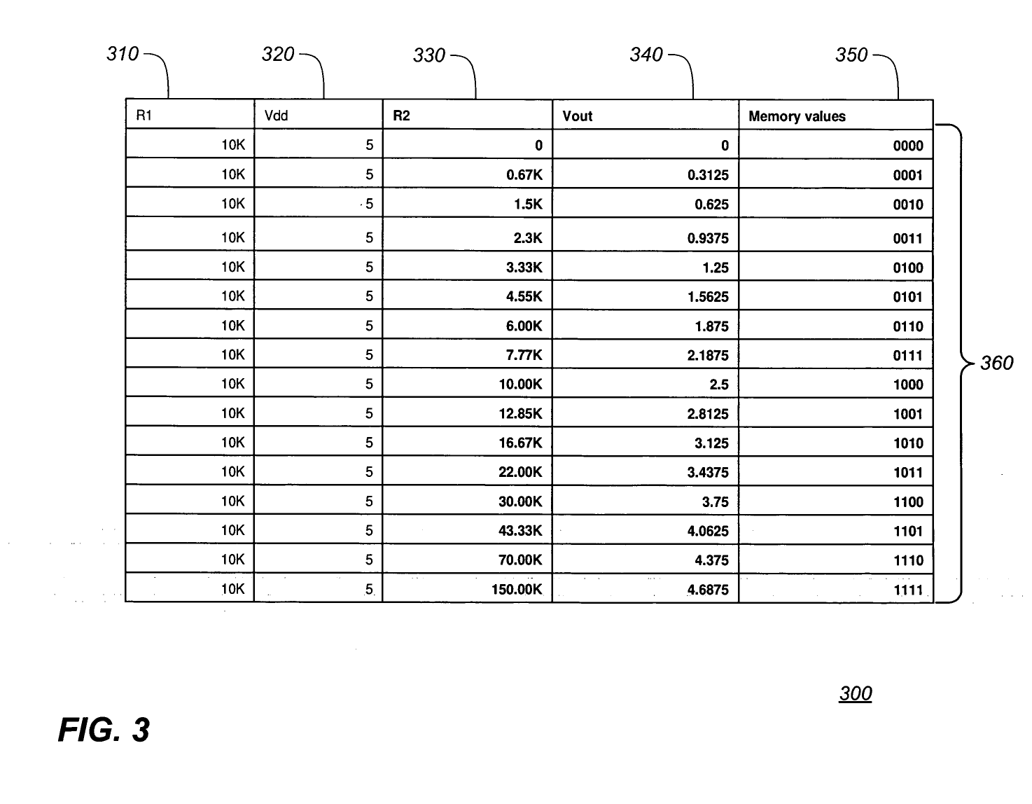

FIG. 3 is a data table 300 showing the resistance memory relationship that may be used to determine the value of a particular resistor, such as one of the resistors 210 in FIG. 2 for a read-only-memory in accordance with a possible embodiment of the invention. In particular the data table has a reference resistor (R1) 310, supply voltage (Vdd) 320, memory resistance (R2) 330, voltage divider voltage (Vout) 340, and memory values 350, and sixteen rows 360 corresponding to the number of bits (2⁴). Notice that as one moves down row 360, memory values change with a change in memory resistor (R2). The analog-to-digital converter can map these values by converting the voltage levels to the appropriate memory values as shown in data table 300.

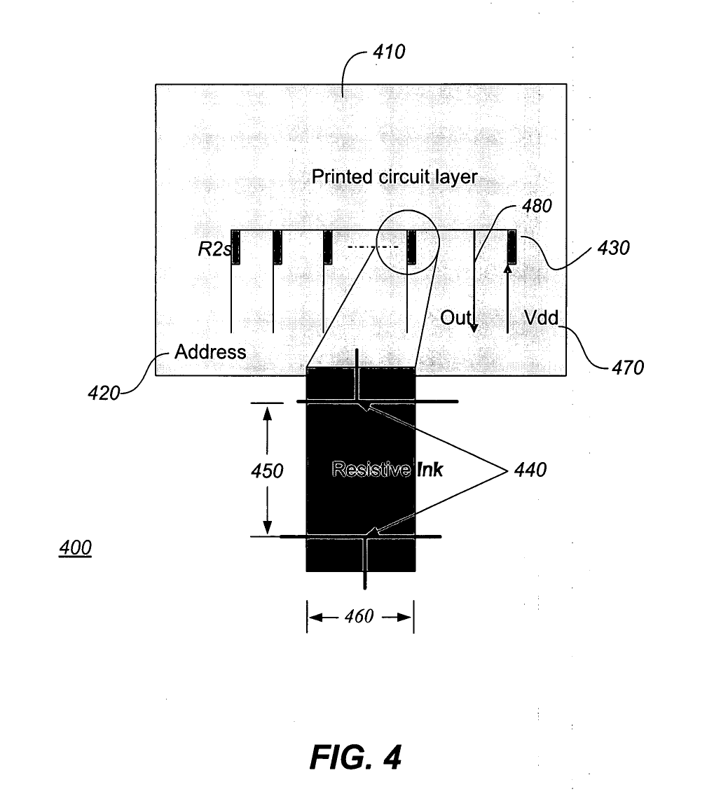

FIG. 4 illustrates a printed circuit and printed memory 400 in accordance with a possible embodiment of the invention. In particular, a printed circuit layer 410, a printed memory, 430, address lines 420 nodes, output node 480, voltage source 470, and resistive and conductive ink layout 440. This arrangement shows that the printed memory 430 is voltage compatible with hybrid controller circuits in the printed circuit layer 410, no cross links are necessary, unlike in traditional ROM circuits, only two material layers are necessary, and since the resistor represents bits of data the circuit can be more compact. Printed resistor array consists of only two layers, conductive trace terminal layer and resistive layer. Resistance is dependent on sheet resistance of the resistive ink, the length 450 (L), the width 460 (W) and the thickness of the resistive layer between the two conductive terminals 440. The resistance of the printed resistor can be accurately adjusted by resistivity of the resistive ink and printed resistor geometry. With minimum number of materials required to print resistor array, it is easy to be integrated in the process during signage display printing, thus streamline the manufacturing.

Although in a fully printed system, transistors might be needed in the analog-to-digital circuit (A/D), the total number of transistors is greatly reduced. In addition, the circuit can be easily separated and printed on the driver substrate, thus significantly reduces the cost of the replaceable printed parts. In the case of hybrid systems 400, the supporting circuit 410 can be easily implemented by silicon circuit, leaving only the resistor array 430 to be on a flexible and disposable printed display. The cost reduction and increase of manufacturing yield open great market opportunities for printed electronic products.

During the manufacturing process, the stored data in read-only memory is designed and manufactured with the circuit. The resistive inks 440 represent memory values that can be used to decode the DNA of various applications including signage poster, flexible display ID type specifications, birthday card with music, printed interactive devices to store responses and answers, program software instructions in printed computer system, and printed electronic tickets. These memory values when processed by a computer such computer 102 in FIG. 1 causes software to be activated or software output/response to be customized based on the data stored in ROM 430. With the data from ROM 430, an advertisement may be selected based on the data so that the advertisement is geared towards a particular location, store profile, individual, or geographical region.

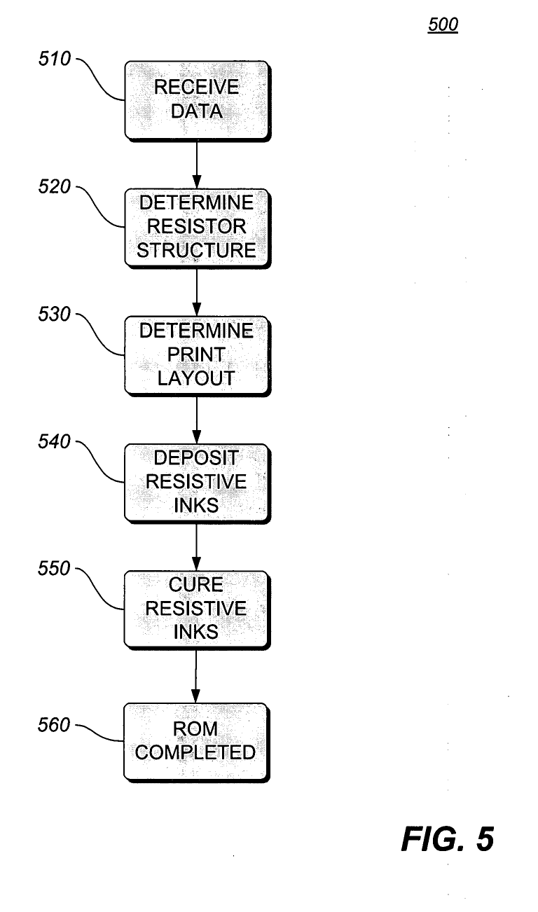

FIG. 5 illustrates method 500 for manufacturing an ink printed resistive read-only memory in accordance with a possible embodiment of the invention. In particular, data is received 510, a resistor structure is determined 520, a print layout is determined 530, resistive ink is deposited 540, resistive ink is cured 550, a ROM is completed 560 from the previous steps.

Method 500 begins with receiving data 510. Step 510 receives data for the read-only memory. The memory takes the form of the sequences of bits as in column 350 in FIG. 3. Resistance values are dependent on the data to be stored. In step 520, a resistor structure is determined from the received data in step 510. Based on the received data 510, information such as the number of bits can be determined, the number of address lines and the number of resistors in the memory array can be determined from the number of bits, and the reference resistor and voltage source (Vdd) values can be arbitrarily chosen. In step 530, a print layout is determined from the resistor structure. The print layout would look similar to ROM 136 in FIG. 2.

In step 540 resistive ink is deposited on the print layout. As a general rule, printed resistance can be defined as follows: R=Ω(L/A) where R=resistance; Ω=bulk resistivity of the ink; L=length of printed resistive ink in between of two conductive terminated pads; and A=cross sectional area of the resistor. The cross-sectional area of the resistor ink in turn equals the product of the print thickness (T) and the width (W) of the resistive ink. Substituting these parameters yields the following formula for the resistance of a printed resistor: R=Ω(L/TW) Thus the resistance of a printed resistor is a function of the bulk resistivity of the ink used to print the resistor, the length of the resistor ink, the thickness of the printed resistor ink and the width of the printed resistor ink. Resistors having different resistances can thus be produced by varying any of these parameters. Thus, the resistance value is based on the ink and the length and thickness of the ink being used in the process. Different printing techniques could be used for printing the resistors on a carrier material such as photolithography, flexography, gravure, and screen printing. Screen printing provides the benefits of high solids loading and layer thickness, and may be used on a broader range of materials. In addition, the equipment is less expensive than for photolithography, flexography, or gravure. However, screen printing is generally slower than the three processes mentioned above, and the print resolution is generally lower than for those processes.

An ink printed resistor is manufactured through known printed electronics process that include some of the following attributes: flexible substrate like plastic and paper; conductors such as PTF conductors, conductive polymers, crgano-metallics, nanoparticle inks, and metal foils; dielectrics such as PTF dielectrics, polymer, and oxides; actives such as polymers, oligomers, and inorganics; and, inks that have high mobility, solution processable, compatible with printing platforms and other inks, matching work function, in-air stability, and environmentally friendly.

A single resistive ink 540 could be used to make memory array resistor and reference resistor, but this would require very large and long resistor layouts to print high-ohm resistors. A preferred method for fabricating resistors is to print multiple resistive inks.

Another procedure is to select plurality of inks such that when blended in a predetermined proportion, the resistivity of the blended ink is optimized, based on the target resistance value and a desired dimensional layout of the ink upon the substrate. For this method, the inks may be deposited in a single pass, with a wet ink being printed on top of another wet ink that was deposited earlier.

In step 550, the deposited resistive inks are cured. A cure step, either in between deposition of each dissimilar material, or after deposition of both dissimilar materials may occur using an infrared cure technique, oven cure, hot air, ultraviolet curing, microwave energy, or inductive heating. In some applications, build up of material consisting of a multitude of ink deposition 540 steps may require a dry or cure step between each material deposition step for proper device fabrication. This dry step may occur using any of the previously mentioned cure techniques and may occur at a multitude of temperatures.

In step 560, the ROM is completed and ready to be used with any data processing device that may be in need of the stored data.

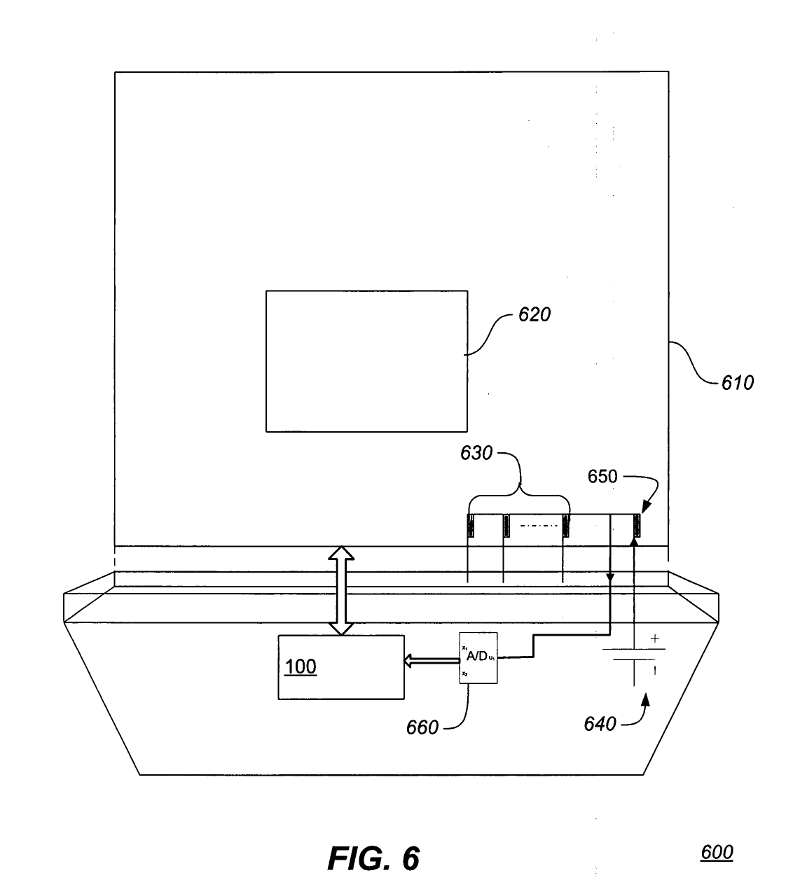

FIG. 6 illustrates an exemplary diagram of a signage system 600 employing a printed electronic circuit (ROM) for causing a controller to activate a signage or advertisement presentation in accordance with a possible embodiment of the invention.

In particular, the signage employing a printed electronic circuit has a signage 610, an information area 620, a voltage source 640, reference resistor 650, and analog to digital converter 660, and controller 100 as described in FIG. 1. The driver circuit consists of voltage source 640, reference resistor 650, and analog to digital converter 660.

The signage system 600 includes a carrier material 610. The carrier material could be at least partly formed from an inexpensive, flexible material such as paper or plastic film. An electronic display device 620 may associated with the carrier material 610. For example, the electronic display device 620 may be formed in or on the carrier material 610.

Low-cost processes to form the electronic display device 620 include printing by means of ink jet, laser, or silkscreen. Such printing techniques can be used to apply image-forming elements such as pixels and associated driving electronics directly onto the carrier material 610. The image-forming elements and driving electronics may comprise semi-conductive polymeric inks, and or conductive polymers applied through known printing process. The carrier material 610 may also include a static image or advertisement.

The controller 100 may comprise programmable logic circuitry such as a processor and/or application-specific integrated circuit. The electronics of the display device 620 may comprise organic light emitting diodes, light emitting polymer, electrophoretic display technology, electro-chromic devices, or nematic or cholesteric liquid crystal devices that may be printed on the carrier material 610, for example, as described above. An image displayed on the display device 620 may be monochromatic or in color.

The controller 100 may provide addressing and data logic for driving displays on the display device 620. The displays could be at varying levels of resolution, with corresponding technologies in the controller 100. In the preferred embodiment controller 100 contains instructions for causing a display or other devices attached to controller 100 such as speakers 126 or 124 to initiate an advertisement message. The advertisement message or other information usable by controller 100 can be stored in memory array 630. Memory array 630 can be printed on carrier material 630 during the printing process.

Embodiments within the scope of the present invention may also include computer-readable media for carrying or having computer-executable instructions or data structures stored thereon. Such computer-readable media can be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium which can be used to carry or store desired program code means in the form of computer-executable instructions or data structures. When information is transferred or provided over a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable media.

Computer-executable instructions include, for example, instructions and data that cause a general purpose computer, special purpose computer, or special purpose processing device to perform a certain function or group of functions. Computer-executable instructions also include program modules that are executed by computers in stand-alone or network environments. Generally, program modules include routines, programs, objects, components, and data structures, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Although the above description may contain specific details, they should not be construed as limiting the claims in any way. Other configurations of the described embodiments of the invention are part of the scope of this invention. For example, the principles of the invention may be applied to each individual user where each user may individually deploy such a system. This enables each user to utilize the benefits of the invention even if any one of the large number of possible applications do not need the functionality described herein. In other words, there may be multiple instances of the method and devices in FIGS. 1-6 each processing the content in various possible ways. It does not necessarily need to be one system used by all end users. Accordingly, the appended claims and their legal equivalents should only define the invention, rather than any specific examples given.

We claim:

1. A signage system having a carrier material, an electronic display device associated with the carrier material, a controller coupled to the electronic display device, and a memory coupled to the controller to store content displayable on the electronic display device, the signage system comprising:
a plurality of ink printed resistors on the carrier material, wherein each ink printed resistor represents at least one bit of data; and
a driver circuit for coupling one or more of the ink printed resistors on the carrier material to the controller comprising:
a reference ink printed resistor coupled to the plurality of ink printed resistors;
a voltage source coupled to the reference ink printed resistor;
an analog to digital converter coupled to the plurality of printed resistors and the reference printed resistor.

2. The signage system of claim 1, wherein the number of printed resistors determines the number of bits to be stored in the plurality of printed resistors.

3. The signage system of claim 2, wherein the voltage source value is divided into 2^{N} values, where N is the number of bits each printed resistor represents.

4. The signage system of claim 2, wherein the voltage level is converted to corresponding bit value by the analog to digital converter.

5. The signage system of claim 1, wherein the resistance value for each printed resistor is dependent on the data to be stored.

6. The signage system of claim 1, wherein a printed resistor is disposed of resistive ink.

7. The signage system of claim 1, wherein the analog to digital converter is operable to measure a voltage level.

8. A read only memory card, comprising:
a flexible carrier material;
a plurality of resistors ink printed on the flexible carrier material, wherein each resistor represents bits of data;
a reference resistor ink printed on the flexible carrier material and coupled to the plurality of resistors;
a source voltage node coupled to the reference resistor; and
an analog to digital converter node coupled to the plurality of resistors.

9. The read only memory device of claim 8, further comprising:
an ink printed analog to digital converter coupled to the analog to digital converter node.

10. The read only memory device of claim 8, wherein the resistance value for each resistor is dependent on the data to be stored by each resistor.

11. The read only memory device of claim 8, wherein the plurality of resistors and reference resistor are disposed of resistive inks.

12. The read only memory device of claim 8, further comprising a set of address connections, each address connection being coupled to a node of one of the resistors representing bits of data, the node being the node of the one of resistors that is not coupled to the analog to digital converter node.

13. The read only memory device of claim 8, wherein an analog to digital converter divides a voltage level into 2N values, where N is the number of bits each of the plurality of resistors represents.

14. The read only memory device of claim 13, wherein the voltage level is converted to corresponding bit value by the analog to digital converter.

15. An electronic device comprising:
a first device including a controller, an electronic display operatively connected to said controller, a read only memory card interface operatively connected to said controller, wherein the operation of said controller is controlled by a sequence of instructions; and
a read only memory card having a substrate with ink printed resistors, each having a resistance value that is converted to a datum used to specify one of the sequence of instructions;
wherein said read only memory card is configured for connection with said interface such that data that is read from the read only memory card is used to form the sequence of instructions.

16. The electronic device of claim 15 wherein said electronic device is one of point of sale display, a signage, advertisement.

17. The electronic device of claim 16 wherein said first device includes a reference resistor and an analog to digital converter coupled to the ink printed resistors.

18. The electronic device of claim 15, wherein the number of ink printed resistors determines the number of bits in the read only memory.

19. The electronic device of claim 17, wherein the resistance value for each ink printed resistor is dependent on the data to be stored;
wherein the analog to digital converter is operable to measure a voltage level;
wherein the analog to digital converter divides the voltage level into 2^{N} values, where N is the number of bits each ink printed resistor represents.

20. The electronic device of claim 19, wherein the voltage level is converted to corresponding bit value by the analog to digital converter.
